(19) United States
(12) Patent Application Publication
(10) Pub. No.: US 2015/0009621 A1
(43) Pub. Date: Jan. 8, 2015

(54) SERVER TUNNEL

(71) Applicant: Frank Baldinger, Merdingen (DE)

(72) Inventor: Frank Baldinger, Merdingen (DE)

(21) Appl. No.: 14/371,694

(22) PCT Filed: Jan. 8, 2013
(86) PCT No.: PCT/EP2013/000027

§ 371 Date: Jul. 10, 2014

(30) Foreign Application Priority Data
Jan. 11, 2012 (DE) 10 2012 000 361.7

(51) Int. Cl. H05K 7/20

(52) U.S. Cl. CPC H05K 7/20745; H05K 7/20781
USPC 361/679.47; 361/679.48; 29/825

(57) ABSTRACT

A computing center module with a module casing and a module area in which electronic devices are arrangeable, at least one access path being provided in the module area. The module area has a hot air outlet region, and the module casing tapers towards the hot air outlet region such that a natural cooling process is allowed. The computing center module is easily and inexpensively produced, requires little surface area, can be cooled efficiently and inexpensively, and offers the possibility to scale the provided module area as needed in a simple manner and to protect against specific environmental risks. The module casing is formed by a pipe which is closeable at the axial ends, and the module casing is provided with at least one movable coupling device for connecting to another computing center module casing such that a common module area is produced when the module casings are connected.

### FIELD OF INVENTION

The invention relates to a computing-center module having a module casing and a module space, in which electronic devices are, or can be, arranged, wherein at least one walk-along aisle is present in the module space wherein the module space has a hot-air-withdrawal region and the module casing tapers in the direction of the hot-air-withdrawal region, wherein the module casing is formed by a pipe which is, or can be, closed at the axial ends, and wherein the module casing has at least one coupling device for connection to the module casing of a further computing-center module such that, when the module casings of two modules are connected, a joint module space is the result.

### BACKGROUND

Such modules, which are intended to achieve the improved dissipation of the quantities of heat which occur in data processing, are known, for example, from US 2011/0232209 A1 or EP 2 348 803 A1.

The progressing digitization of society has resulted in it being customary for private individuals or households and professional and official organizations to store, and process, much data digitally.

This gives rise to huge quantities of data which are processed, and stored, in computing centers. These computing centers in some cases contain thousands of servers (computers), memories, routers and other network hardware, referred to herein below together as server hardware. All these electronic devices have a fairly high level of power loss, which is dissipated in the form of heat. This gives rise to huge quantities of heat in a computing center.

The server hardware is relatively sensitive to heat and it is therefore the case that it can be used, and is efficient, only in a limited temperature range. For this reason, the quantity of heat which occurs has to be removed, so that the temperature does not exceed a critical value and adversely affect the performance.

It is therefore necessary to have wide-ranging devices for cooling the server hardware, for example air-conditioning installations. These cooling devices require, in some cases, more (electrical) energy than the server hardware itself. Cooling therefore also has to be included in the efforts to achieve more energy-efficient computing centers.

In order to cut back on energy for the cooling, some computing centers are already located in cold regions, where the environment, for example cold seawater or cold air, can be used for cooling purposes.

The servers are usually accommodated in buildings designed specifically for this purpose, for example in large industrial buildings, since the operations of setting up, cabling and maintenance are easy to manage there. The disadvantage here is that usually the entire space or the entire building has to be cooled to the operating temperature of the server hardware.

One possible way of reducing the cooling costs is to arrange the server spaces in individual, closed-off computing-center modules. Cooling can then be limited to the significantly smaller modules, and there is therefore no need to cool the entire computing-center building.

A further cost factor in the construction and operation of computing centers is the amount of space required for the server installations or the modules. The server spaces require a large surface area, and this makes it difficult in particular to locate them in climatically attractive regions, since there are not usually any large surface areas available there.

Here too, the arrangement in individual computing-center modules has the advantage that more or less any desired spaces can be set up straightforwardly to form computing centers.

This means that it is also readily possible to fit out existing, no longer required buildings, which were not originally planned and equipped as computing centers.

In addition to the modules for accommodating the server hardware, it is also possible for the cooling installations and the power supply to be of modular construction. The computing-center modules may be flexibly set up and combined as required, and this means that straightforward scaling of the computing power is readily possible.

However, the large amount of surface area required is still a concern, since the modules can be stacked predominantly one beside the other and, in individual cases, also one above the other. In addition, it is not always possible to use existing buildings, in particular in climatically attractive regions.

### SUMMARY

It is therefore an object of the invention to provide a computing-center module for accommodating the electronics which is straightforward and cost-effective to produce, requires only a small amount of surface area and can be cooled efficiently and cost-effectively, and which makes it possible in a straightforward manner for the module space available to be scaled as required and safeguarded against certain environmental hazards.

This object is achieved according to the invention by a computing-center module having one or more features of the invention.

The computing-center modules have a hot-air-withdrawal region which is formed by a tapering module casing. The hot waste air rises of its own accord. The tapering module casing causes the waste air to collect in the hot-air-withdrawal region. This also gives rise, in addition, to a suction effect like that in a chimney, and assists the hot air in being removed from the module space. The hot air collected in the hot-air-withdrawal region can be routed out from there into the surroundings for example via an opening in the module casing. It is also possible, however, for it to be removed through a waste-air line for example via a fan. The module is cooled here in the module space in that the module space has at least one cold-air zone and at least one hot-air zone. Moreover, a floor is arranged all the way along the module space, and two parallel slide-in racks, which are, or can be, equipped with electronic devices are arranged in the longitudinal direction on said floor. A walk-along aisle is formed as a cold-air zone between the racks. Hot-air zones are located in each case between the racks and the module casing, said hot-air zones running into a joint hot-air-withdrawal region.

The module casing here is formed in a particularly expedient manner by a pipe which is, or can be, closed at the axial ends, since this form of module casing has a very good thermal effect and the module space has optimum flow behavior.

In order to increase the space for accommodating server hardware, this space being limited in each computing-center module, it is possible for a plurality of modules to be connected to one another, and therefore the resulting module space can be extended in a scalable manner. For this purpose, it is expedient if the module casing has at least one coupling device for connection to the module casing of a further module. The modules are preferably open at the coupling device, and therefore, when two modules are connected, a joint module space is the result. All the modules thus have a joint hot-air-withdrawal region, from which the collected hot air can be dissipated. This makes it possible to achieve a further improvement in the cooling efficiency, since there is no need for each module to be supplied separately with fresh air.

For the coupling of two modules, the coupling devices are provided in a movable manner, the movement capability being ensured for example by articulations, and this means that an arrangement of a plurality of modules does not break apart in the event of the ground moving, for example due to earthquakes; rather, the articulations make it possible for the modules to execute compensating movements.

Due to hot air being extracted from the module space, there is no need for a fan or air-conditioning, or it is sufficient to have air-conditioning of significantly lower power than in the prior art.

An upward tapering module casing is essential for the thermal ventilation to function. The precise form of module casing, however, is of only secondary importance. The module casing may be, for example, of pyramid design. It is particularly advantageous, however, if the module casing is formed by a hollow body which is rounded at least in the upward direction on the inside.

In an expedient embodiment of the invention, the module casing, in the hot-air-withdrawal region, has an upwardly directed, chimney-like opening, through which the hot waste air can exit from the module space.

A further improvement in the natural cooling can be achieved by the presence, in the flow path to the hot-air-withdrawal region, of a flow restriction, at which the flow speed of the hot waste air is increased. This further enhances the hot-air withdrawal brought about by the tapering of the module casing.

It is particularly expedient if the floor, in the cold-air zone, has openings in the form of a cold-air supply and the cold-air zone is sealed off in the upward direction in relation to the hot-air-withdrawal region. This results in the cold-air zone being separated in structural and spatial terms from the hot-air zones. The air flow is thus forced through the racks, where it cools the server hardware.

In this embodiment, the flow resistance may be formed by in each case the distance between the upper edge of the slide-in racks and the module casing being small.

A further embodiment of the invention comprises the arrangement, in the hot-air zone, of a liquid-cooling body, which is supplied with cooling liquid by way of the floor. This can additionally increase the cooling power without high outlay being required to cool the cooling air supplied. This makes it possible to cut back further on energy. This liquid cooling can achieve enormous cuts, in particular in cold regions, by cold flow water or seawater being used for cooling purposes.

It is also possible for the liquid-cooling body to be arranged, or integrated, in the module casing.

An additional advantage of the computing-center modules according to the invention is that, they can be arranged under ground in order to cut back on the amount of surface area required above ground.

For this purpose, the module casing is preferably stable enough to bear the load of the surrounding soil and any buildings which may be standing thereon.

In particular it is possible for the module casing to be produced very cost-effectively from concrete. All other expedient materials are nevertheless conceivable.

The arrangement of the computing-center modules under ground means that, in practice, no surface area is required for a computing center. The modules may be arranged beneath buildings, beneath parking lots, in hills or mountains or under water. It is also possible for the modules to be located in regions with ground on which it is not possible to build, for example marshland or intermittently thawing permafrost.

The modules may be arranged, for example, in a trench, which, following assembly, is filled in. It is also possible, however, for the modules to be slid into a tunnel or gallery which has been mined beforehand. Straightforward assembly means that the operation of laying the modules is not subject, in practice, to any limitations. It is therefore also readily possible for the modules to be extended as required.

There are no restrictions governing the operation of laying the modules and the module chains. It is thus possible, for example, for a plurality of linear module chains to be arranged in a star shape around a joint central space. The central space here may be located at a higher level and serve as a central waste-air exit. For this purpose, the module chains are preferably arranged so as to slope up to said space.

Ideally, in addition to the electric lines, the modules require only a cold-air supply and a hot-air dissipating means. When a plurality of modules are coupled to one another to form a chain, all the connections are included in the coupling, and this readily ensures supply to all of the modules.

In order to assist the natural ventilation function, it is possible for such a module chain to be installed in a slightly inclined manner overall, and therefore the hot air rises not just into the hot-air-withdrawal region, but also along the upwardly sloping module chain.

In addition, it is even possible for the environment of the modules to be used for cooling purposes.

In addition to efficient cooling, the underground arrangement provides for an enhanced safeguard against environmental incidents, for example earthquakes, tornados or flooding, and against acts of terror or war.

A further advantage of the module according to the invention is that it can be fully prefabricated. This also includes the installation of the server hardware. All that is therefore required is for the completely finished and ready-to-operate module to be transported to the site of installation and installed there. In the case of a computing center having a plurality of modules, it is also necessary for the individual modules to be connected to one another.

In the case of modules in the form of pipes, the axial ends of the pipes can be closed off for transportation purposes by a sheet material or a fixed cover. This closure can remain on the end module even in the installed state.

A further advantage of the computing-center module according to the invention is that the modules can be produced in a straightforward and cost-effective manner.

A particularly advantageous method is one in which the module casing is produced first of all. Thereafter, the server hardware and all of the supply-air and waste-air lines are installed, ready for operation. Finally, the finished module is transported to the site of installation and installed.

The operations of producing the module and of installing the server hardware can take place at the same location. It is also possible, however, for the module casing to be transported, in an intermediate step, to a different location for the installation of the server hardware.

In addition to this, it is also possible for the server hardware to be installed only once the module has been installed, although this is less advantageous.

The server hardware may also be pre-assembled at a different location to form an electronics unit, in which case all that is required is for it to be installed in unit form in the finished module casing.

In addition to the modules being installed directly, it is also possible for these to be slid into a shell system which is prefabricated or present at the site of installation.

### BRIEF DESCRIPTION OF THE DRAWINGS

The invention will be explained in more detail hereinbelow by way of a number of preferred exemplary embodiments and with reference to the accompanying drawings, in which:

FIG. 1 shows a hollow body according to the invention in the form of a pipe with equipped server cabinets,

FIG. 2 shows a cross section through a server tunnel with air cooling,

FIG. 3 shows a cross section through a server tunnel with liquid cooling,

FIG. 4 shows a cross section through a server tunnel with liquid cooling and a waste-air chimney,

FIG. 5 shows a cross section through a server tunnel with shell cooling,

FIG. 6a shows a plan view of a coupling between two server tunnels,

FIG. 6b shows a chain having a plurality of server tunnels coupled to one another,

FIG. 7 shows a detail-form view of a coupling,

FIG. 8 shows a variant of the server tunnel in the form of a slide-in unit for an enclosing pipe,

FIG. 9 shows a cross section of the server tunnel with slide-in unit,

FIG. 10 shows a server-tunnel slide-in unit with a slide-in pipe which has been laid beforehand,

FIG. 11 shows individual production steps for a server tunnel,

FIGS. 12(a) and 12(b) show method steps for laying a server tunnel under ground,

FIGS. 13(a) and 13(b) show method steps for laying a server tunnel partially under ground,

FIG. 14 shows an illustration of a server tunnel being laid under the ground, and

FIG. 15 shows an illustration of a server tunnel being laid in a hill or mountain.

### DETAILED DESCRIPTION OF THE PREFERRED EMBODIMENTS

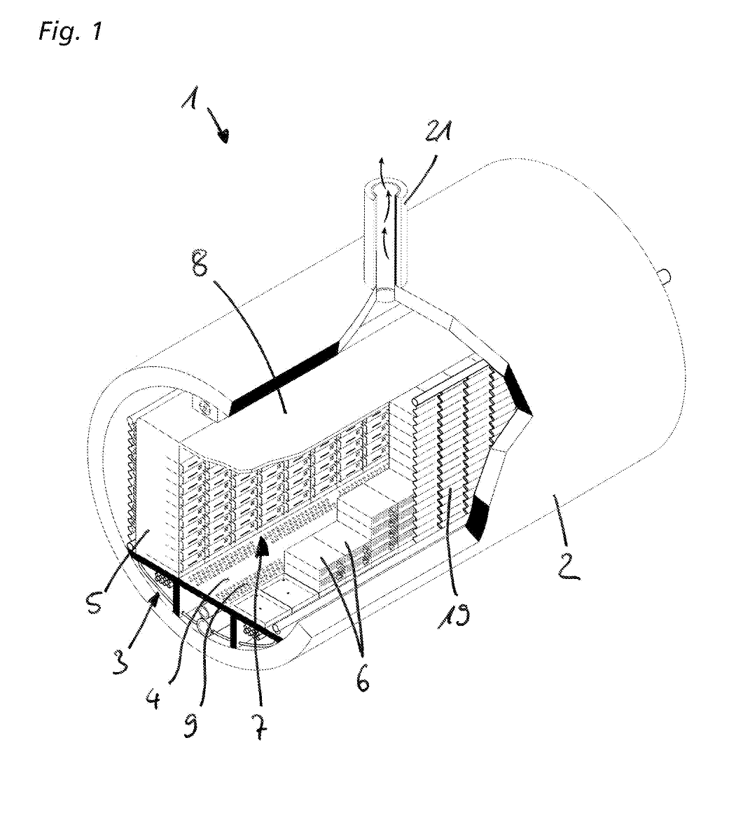

FIG. 1 shows a preferred embodiment of a computing-center module 1 according to the invention. The module casing 2, in the example, is designed in the form of a pipe and is produced from concrete. The diameter and the length of the pipe in the example are each approximately 4 m. It is, of course, possible for both the material and the diameter and length to be varied more or less as desired.

These dimensions, however, allow straightforward and cost-effective production and straightforward transportation of the modules 1.

The module casing 2 bounds a cylindrical module space 3. A module floor 4 is arranged in the module space 3. Slide-in racks 5, in which server hardware 6, such as computers, memories, switches, routers or other electronic components are arranged, are arranged in the longitudinal direction on the module floor 4. The racks 5 are arranged parallel to one another, and therefore a walk-along aisle 7 is present in the center. The aisle 7 is closed off in the upward direction by a ceiling 8 between the upper ends of the slide-in racks 5. The floor 4 of the aisle 7 contains a plurality of openings 9, through which fresh, cold air 10 can flow into the aisle 7. The air is supplied through fresh-air lines 11 running beneath the floor 4.

The aisle 7 thus forms a cold-air zone 12. The server hardware 6 is arranged in the slide-in racks 5 such that the cold air 10 is taken in from the aisle 7 and blown out again on the rear side of the racks 5. The rear side of the racks therefore bounds a hot-air zone 13 in each case with the module casing 2.

The rounding of the pipes causes the module casing 2 to taper upward. This gives rise, at the upper narrowing of the module casing 2, to a hot-air-withdrawal region 14, in which hot air 15 collects and can be removed efficiently from there.

The round or rounded shape of the module casing 2 here is just one possible embodiment. It is also possible for the module casing to taper to a point or to be graduated.

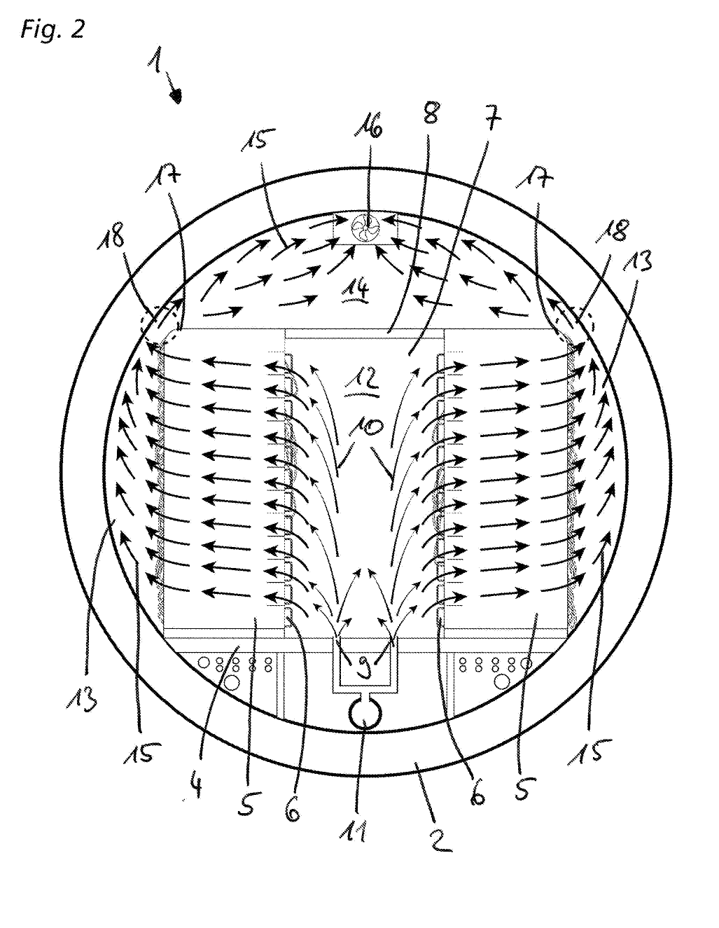

FIG. 2 shows a first embodiment of the invention, in which cold air 10 is routed through the floor 4 into the aisle 7, cold here relating to the temperature of the server hardware 6. Depending on the heat developed by the server hardware 6, it is also possible for the temperature of the cold air 10 to be 20° C. and more.

The cold air 10 flows along the server hardware 6, by way of the slide-in racks 5, and exits into the hot-air zone 13 on the rear side of the racks 5. There, the hot air 15 rises automatically upward in the direction of the central hot-air-withdrawal region 14. Here, the hot air 15 is routed out of the module 1 in the axial direction via a fan 16. The rounding of the module casing 2 gives rise to a natural air flow in the upward direction, and therefore a significantly lower fan power is sufficient in order to dissipate the hot air 15.

In addition, the slide-in racks 5 are arranged such that the upper outer edge 17 is located in the vicinity of the module casing 2. This gives rise to a narrowing 18 in the flow path of the hot air 15. This flow resistance 18 accelerates the hot waste air 15 to give an additional suction effect, which draws the cold air 10 out of the aisle 7 and through the racks 5.

The hot-air-withdrawal region 14 is closed off in relation to the aisle 7, that is to say the cold-air zone 12, by the ceiling 8, and therefore the cold air 10 is not extracted directly from the aisle 7.

The cold air 10 is guided through a cold-air line 11 beneath the floor 4 and is routed into the aisle 7 through openings 9 in the floor 4.

In addition to optimized flow within the module space 3 and the fan power being reduced as a result, the volume of the cold-air zone 12 is relatively small, and therefore the quantity of cooling air required is smaller overall.

In order to increase the cooling power further, liquid cooling may be present in addition to air cooling.

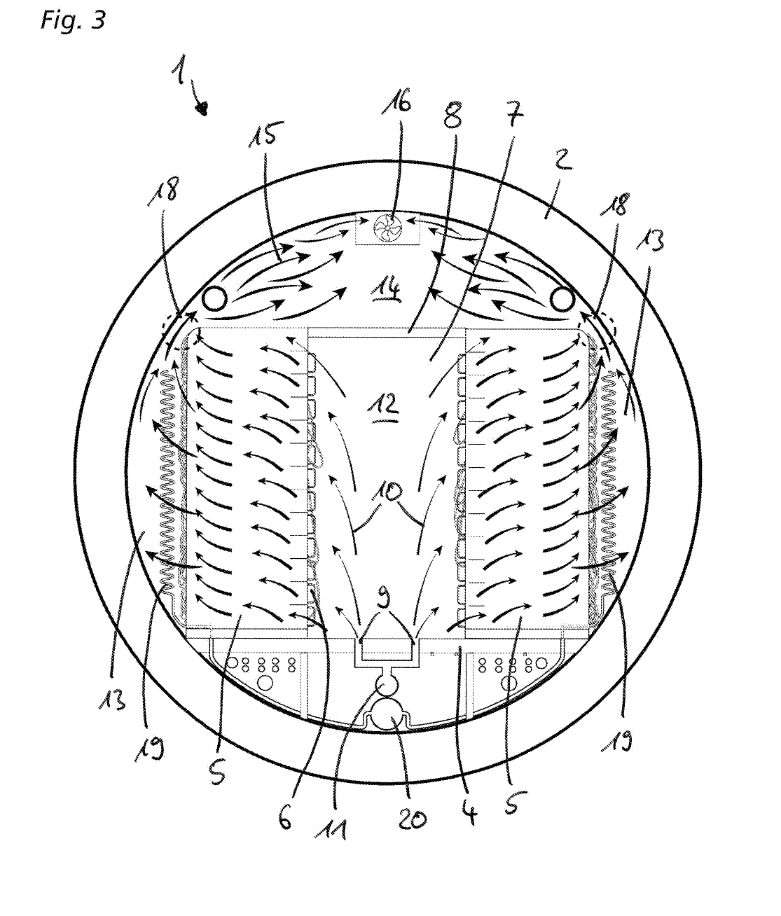

FIG. 3 shows a first embodiment of such liquid cooling. For this purpose, the hot-air zones 13 contain cooling bodies 1 immediately behind the racks. The cooling bodies 19 have cooling liquid flowing through them and thus withdraw additional heat from the hot air 15. The cooling liquid is routed through cooling-liquid lines 20 beneath the floor 4.

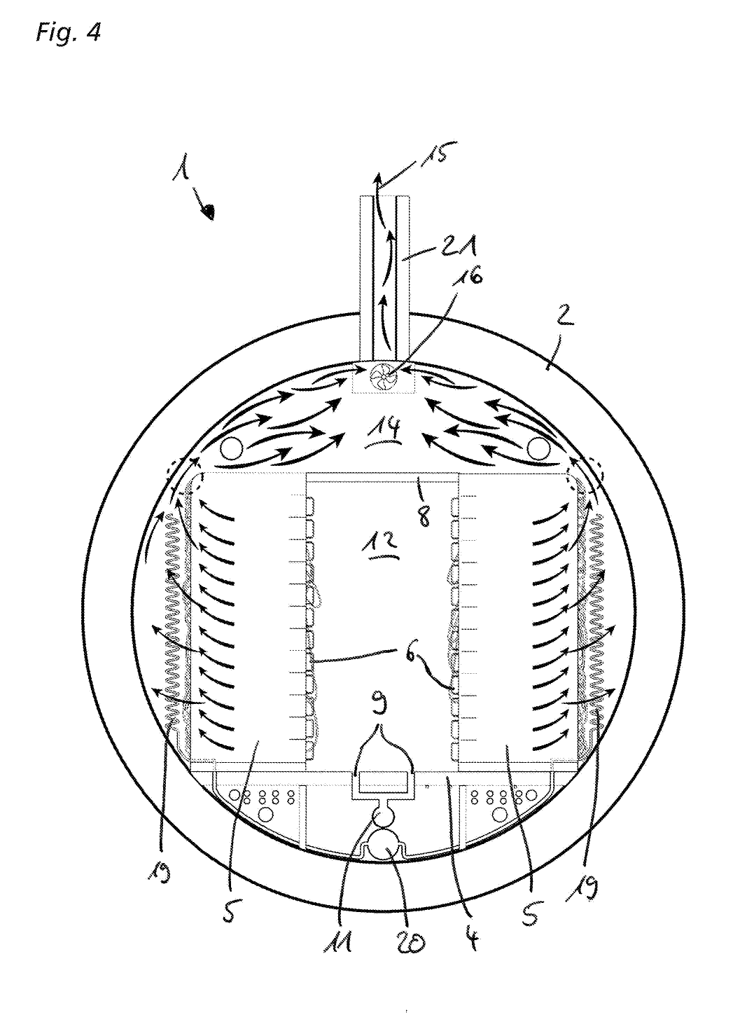

FIG. 4 shows an alternative embodiment, in which the hot air 15 is not routed in the axial direction out of the module 1. Instead, the hot-air-withdrawal region 14 contains a vertical chimney 21, through which the hot air 15 is routed in the upward direction out of the module 1. This chimney 21, as shown in FIG. 1, is arranged preferably approximately in the center of the module 1. It is also possible, however, for it to be arranged at the end of a module or at some other location therebetween. The example shows the chimney 21 together with a liquid-cooling means 19. It is nevertheless fully independent thereof.

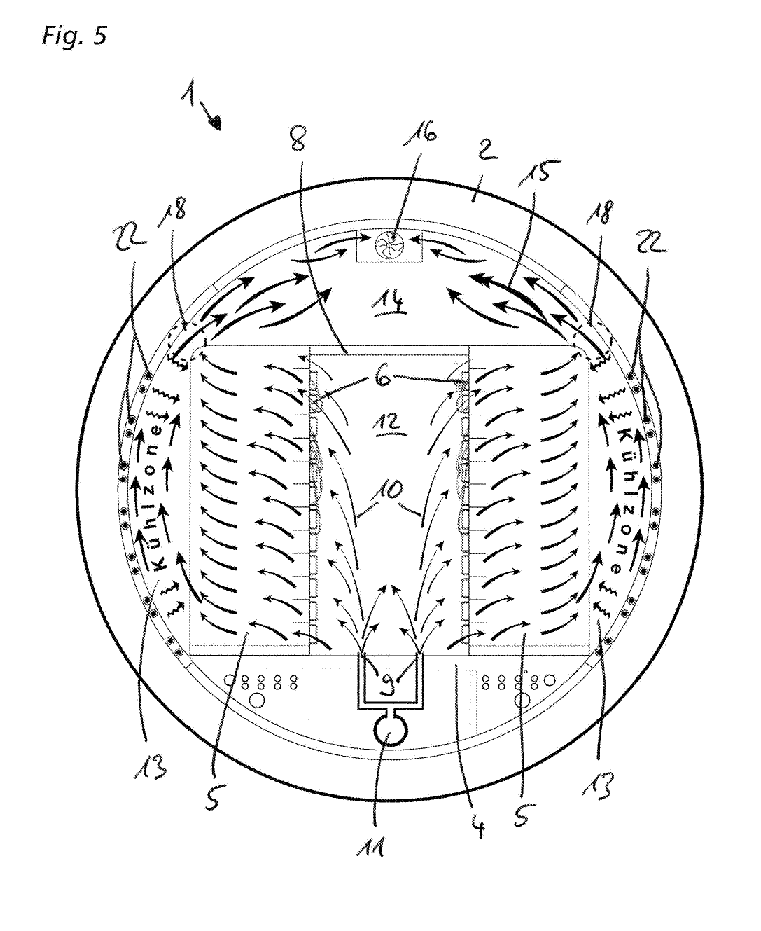

Instead of being arranged behind the racks 5, it is also possible for the liquid-cooling bodies 19 to be arranged in the module casing 2, as illustrated in FIG. 5. The cooling liquid here is guided through a plurality of lines 22 in the module casing 2. In addition, it is possible for the module casing 2 to consist of a different material, in particular a material with good thermal conductivity, in the region of the liquid lines 22.

The computing-center modules 1 according to the invention have natural ventilation which, depending on climatic conditions, manages completely without electrical ventilation or air-conditioning. It is thus possible to cut back on much of the energy which is necessary for operating a computing center.

The individual computing-center modules 1 have relatively compact dimensions. In order to extend the installation space for server hardware, it is possible for two or more modules to be coupled to one another. In contrast to computing-center modules according to the prior art, the module spaces of the individual modules here are preferably connected to one another to give a joint module space. This makes it possible to achieve efficient joint cooling.

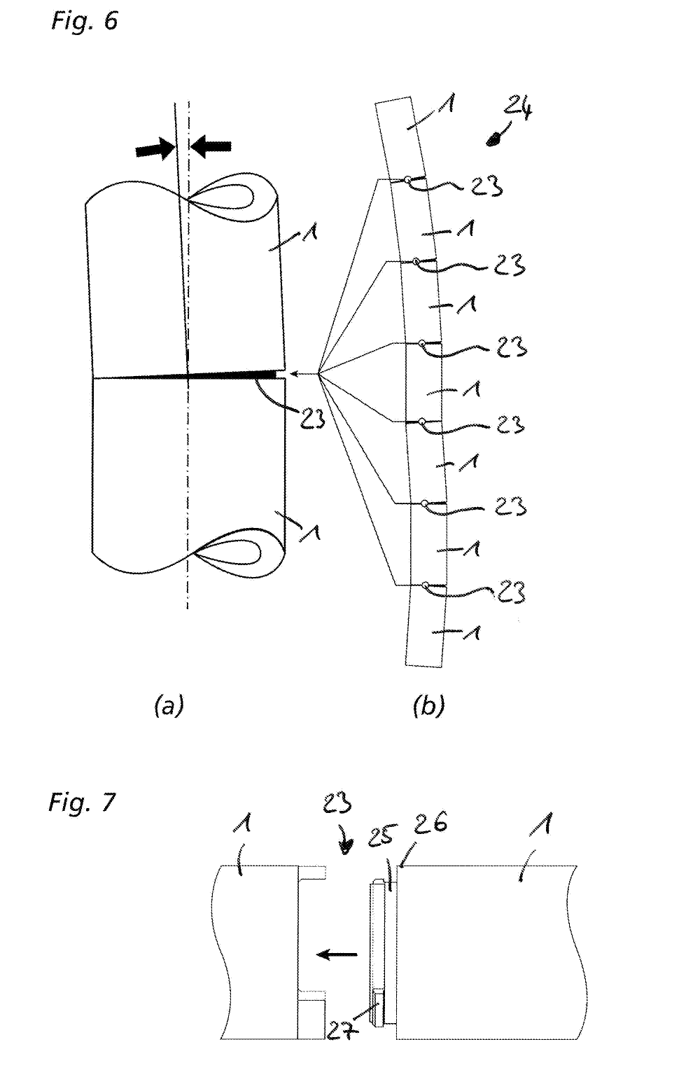

For the purpose of coupling two modules 1, the modules 1 have for example in each case at least one movable coupling device 23 (articulations). FIG. 6b shows a module chain 24 made up of seven modules 1 which are connected to one another in each case by such a coupling device 23. This prevents the module chain 24 from breaking apart in the event of the ground moving, for example on account of earthquakes. Instead, the articulations allow the modules to execute compensating movements, as shown in detail in FIG. 6a.

A possible coupling device 23 for modules 1 in the form of pipes is illustrated by way of example in FIG. 7. The modules 1 each have, at one end, an annular flange 25, which projects beyond the module periphery 26 and has a relatively small diameter. Said flange 25 engages in another module 1, wherein an annular seal 27 seated on the outer circumference of the flange 25 seals the module space 3 in the outward direction.

In addition to the energy costs, the amount of space required for a computing center plays a critical role. The invention therefore proposes to arrange the computing-center modules 1 under ground. This readily makes it possible to cut back on the amount of surface area required above ground. In particular, it is thus also possible to arrange computing centers beneath existing buildings.

The computing-center module 1 according to the invention may have, for example, a stable and sealed module casing 2, and the modules 1 can therefore be installed directly under ground. For example it is possible for the module casing to be produced from concrete.

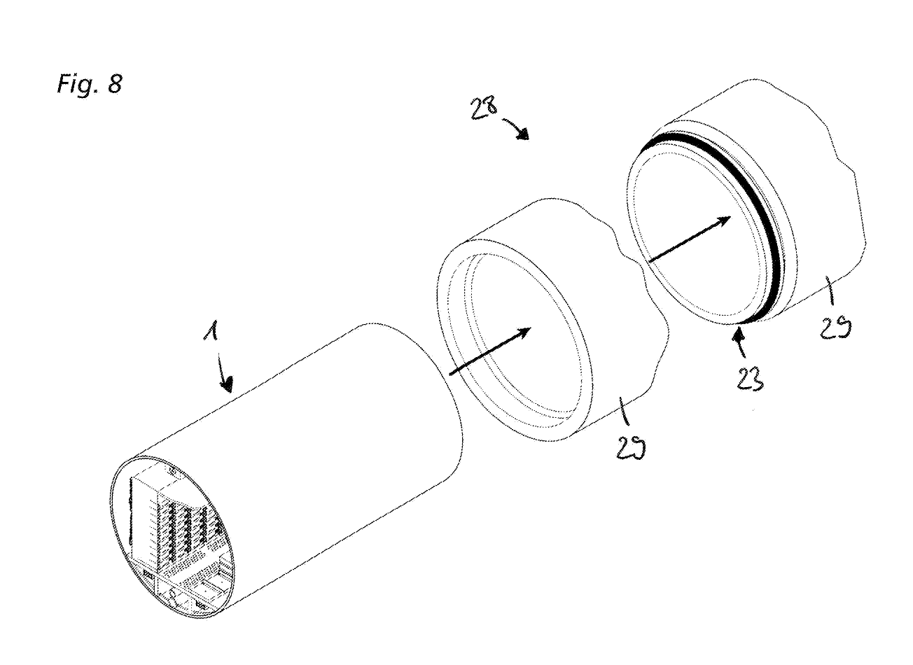

It is also possible, however, for the module casing 2 to be for example just stable enough to be able to bear the server hardware 6. These modules 1 can then be slid for example into a shell system 28, as is illustrated in FIG. 8. It is possible here for the shell system 28 likewise to comprise individual shell modules 29.

The computing-center modules 1 and the shell modules 29 then each have dedicated coupling devices, which can be used to configure larger units.

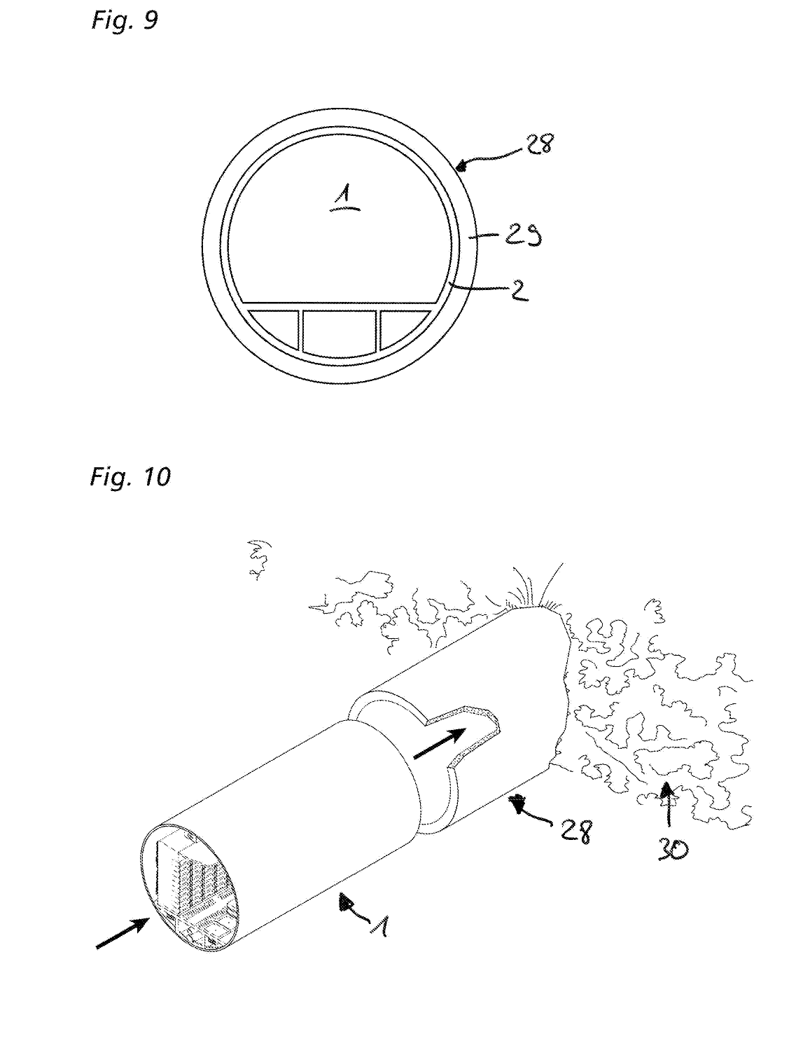

FIG. 9 shows a section through such a shell system 28 with a computing-center module 1 inserted. In particular in the case of such shell systems, the pipe form is advantageous since it is not as easy for the pipes to skew as they are being slid one inside the other.

As is illustrated in FIG. 10, the shell system 28 may be arranged for example in a hill or mountain 30. The computing-center modules 1 are slid into the shell system 28. The walk-along aisle 7 in the computing-center modules 1 provides easy access to the module couplings 23, and therefore assembly work can be carried out easily and quickly on site.

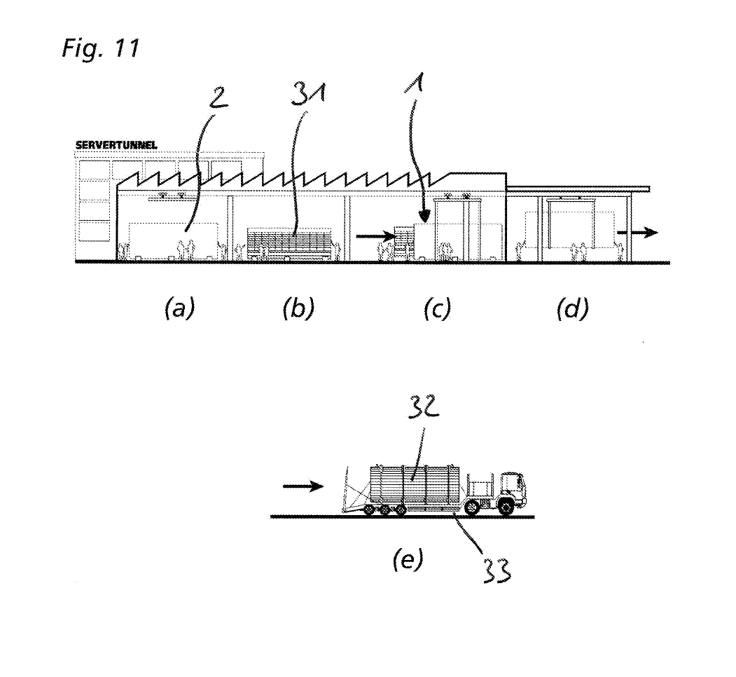

The procedure for producing a computing-center module according to the invention is shown schematically in FIG. 11. First of all, the module casing 2 is produced (see (a) in FIG. 11). If the module casing 2 is a concrete pipe, it can be cast for example in a mold.

The module floor 4, the racks 5, the server hardware 6 and all of the equipment which is further required for operation are combined to form an electronics unit 31 (see (b) in FIG. 11). Account can easily be taken here of individual equipment requirements.

Both the module casing and the electronics unit may be produced beforehand independently of one another.

Thereafter, the ready-to-operate electronics unit 31 is slid into the module casing 2 (see (c) in FIG. 11) and the finished module 1 is prepared for transportation (see (d) in FIG. 11). Finally, the packed module 32 is transported to the site of installation on a low loader 33 (see (e) in FIG. 11).

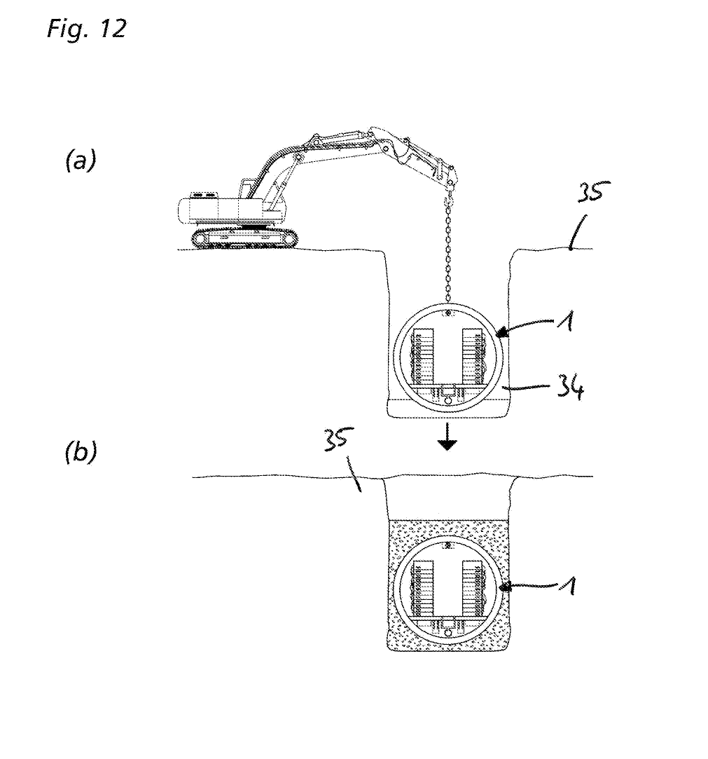

It is possible for example for a pit 34 or some other hollow to be excavated at the site of installation, as is shown in FIG. 12a. The ready-to-operate module 1 is inserted into said pit 34 and possibly connected to further modules 1. The pit 34 in the example is deep enough for the modules 1 to be located in their entirety beneath the ground surface 35. Finally, the pit 34 is filled in again. See FIG. 12(b). It is possible here to make use for example of the material excavated. In order to increase the stability and the resistance, it is also possible for the entire pit 34 to be filled with concrete.

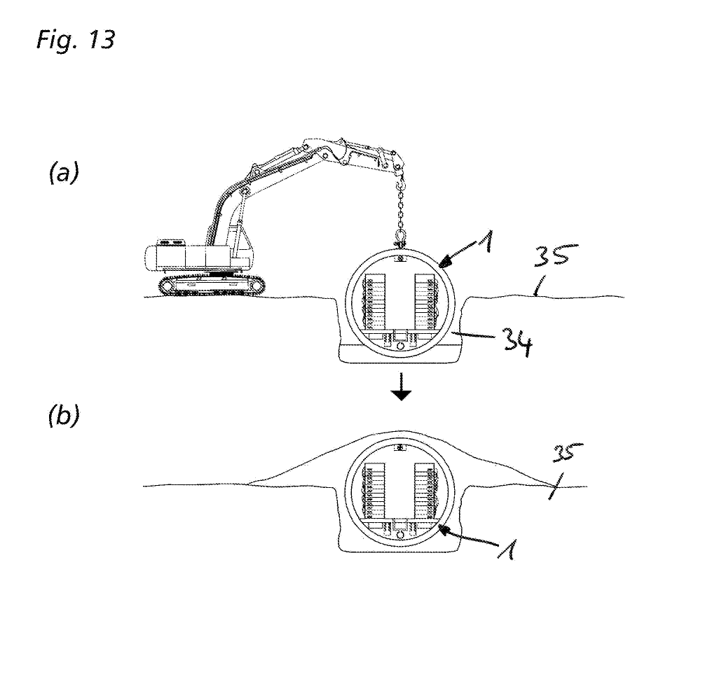

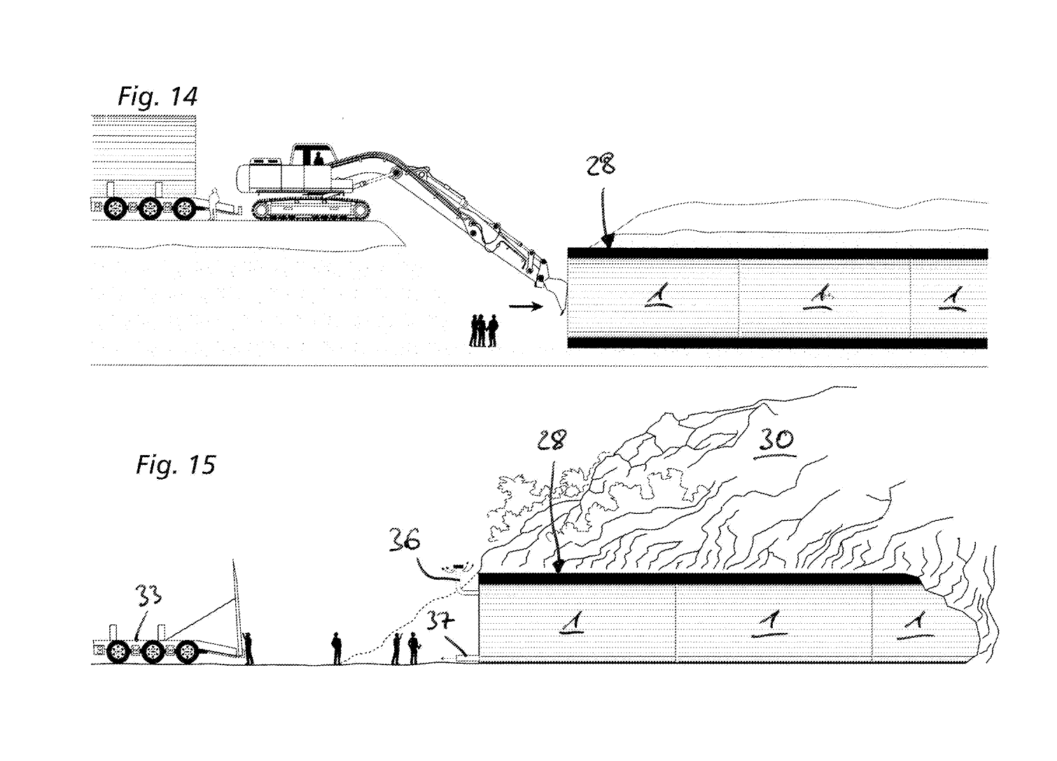

As an alternative, it is also possible for the pit 34 to be less deep, and therefore the modules 1 are located only partially beneath the ground surface 35, as is shown in FIG. 13a. The pit 34 here may be just deep enough for the material excavated to be sufficient for covering the module 1 in its entirety (FIG. 13b). This produces a small mound, which may also be cultivated. The depth of the pit may be freely selected here, even if the material excavated does not cover over the modules.

FIG. 14 shows a further example of how a plurality of computing-center modules 1 may be arranged in an underground shell system 28. The shell system 28 here comprises pipes 29 which, in the first instance, are arranged in a trench 34, as shown, for example, in FIG. 12a. The computing-center modules 1 can then be slid in once the trench 34 has already been filled in again.

Such a shell system 28 may also be arranged in a solid hill or mountain 30. This shell system may be produced, for example, by way of tunnel drilling. As can be seen in the example, the upper periphery has arranged on it a waste-air chimney 36, which is connected to the hot-air-withdrawal region of the modules. A hot-water outflow 37 is arranged on the floor.

1. A computing-center module having a module casing (2) and a module space (3), in which electronic devices (6) are, or can be, arranged, wherein at least one walk-along aisle (7) is present in the module space (3), wherein the module space (3) has a hot-air-withdrawal region (14) and the module casing (2) tapers in a direction of the hot-air-withdrawal region (14), characterized in that the module casing (2) is formed by a pipe which is, or can be, closed at the axial ends, and in that the module casing (2) has at least one coupling device (23) for connection of the module casing (2) to a further computing-center module (1) such that, when the module casings (2) of two modules (1) are connected, a joint module space (3) results, wherein the at least one coupling device (23) is provided in a movable manner in each case.

2. The computing-center module as claimed in claim 1, characterized in that the module casing (2) is formed by a hollow body which is rounded at least in an upward direction on the inside.

3. The computing-center module as claimed in claim 1 or 2, characterized in that the module casing (2), in the hot-air-withdrawal region (14), has an upwardly directed, chimney-like opening (21), through which hot waste air (15) can exit from the module space (3).

4. The computing-center module as claimed in one of claims 1 to 3, characterized in that the module space (3) has at least one cold-air zone (12) and at least one hot-air zone (13).

5. The computing-center module as claimed in one of claims 1 to 4, characterized by the presence, in the flow path to the hot-air-withdrawal region (14), of a flow restriction (18), at which a flow speed of the hot waste air (15) is increased.

6. The computing-center module as claimed in one of claims 1 to 5, characterized in that a floor (4) is arranged all the way along the module space (3), in that two parallel slide-in racks (5), which are, or can be, equipped with electronic devices (6), are arranged in a longitudinal direction on the floor (4), wherein a walk-along aisle (7) is formed as a cold-air zone (12) between the racks (5) and hot-air zones (13) are located in each case between the racks (5) and the module casing (2), said hot-air zones running into a joint hot-air-withdrawal region (14).

7. The computing-center module as claimed in claim 6, characterized in that the floor (4), in the cold-air zone (12), has openings (9) in the form of a cold-air supply and the cold-air zone (12) is sealed off in the upward direction in relation to the hot-air-withdrawal region (14) by a ceiling (8).

8. The computing-center module as claimed in claim 6 or 7, characterized in that the flow restriction (18) is formed by in each case a distance between an upper edge (17) of the slide-in racks (5) and the module casing (2) being small.

9. The computing-center module as claimed in one of claims 4 to 8, characterized by the arrangement, in the hot-air zone (13), of a liquid-cooling body (19), which is supplied with cooling liquid by way of the floor (4).

10. The computing-center module as claimed in one of claims 4 to 8, characterized by the arrangement, in the hot-air zone (13), of liquid lines (22) in the module casing (2), said liquid lines having cooling liquid flowing through them.

11. The computing-center module as claimed in one of claims 1 to 10, characterized in that the module casing (2) is produced from concrete.

12. A computing center having at least one computing-center module (1) as claimed in one of claims 1 to 11 and having at least one cooling device, for supplying the module with fresh air and/or cooling water.

13. A method of producing a computing-center module (1) as claimed in one of claims 1 to 11, characterized by the following method steps:
production of the module casing (2),
installation of the electronic devices (6) in the module space (3),
transportation to the site of installation,
underground installation and connection of the module on site.

14. The method as claimed in claim 13, characterized in that the electronic devices (6) are pre-assembled outside the module space (3) to form an electronics unit (31) and the electronics unit (31) is inserted as a whole into the module space (3).

15. The method as claimed in claim 13 or 14, characterized in that the computing-center module (1) is slid into a shell system (28).
